(19) United States
(12) Patent Application Publication
(10) Pub. No.: US 2014/0065881 A1
(43) Pub. Date: Mar. 6, 2014

(54) MULTI-SOCKET MEMORY MODULE T-CONNECTOR

(71) Applicants: S. Vinay, Bangalore (IN); Ramaswamy Parthasarathy, Bangalore (IN); Shivaprasad Chandramouli, Bangalore (IN); Shanto A. Thomas, Bangalore (IN); Vikas Rao, Bangalore (IN); Aruljothi Kandasamy, Bangalore (IN)

(72) Inventors: S. Vinay, Bangalore (IN); Ramaswamy Parthasarathy, Bangalore (IN); Shivaprasad Chandramouli, Bangalore (IN); Shanto A. Thomas, Bangalore (IN); Vikas Rao, Bangalore (IN); Aruljothi Kandasamy, Bangalore (IN)

(21) Appl. No.: 13/603,384

(22) Filed: Sep. 4, 2012

(51) Int. Cl. H01R 13/66; H05K 3/32

(52) U.S. Cl. 439/620.2; 29/832

(57) ABSTRACT

Embodiments of apparatus, methods, systems, devices, and connectors are described herein for a connector having a longitudinal body configured to mount the connector to a PCB. In various embodiments, a first and a second socket may be respectively disposed at a first side and a second side of the longitudinal body. In various embodiments, the first and second sockets may removably receive a first memory module from a first direction and a second memory module from a second direction opposite to the first direction. In various embodiments, the second side may be opposite to the first side. In various embodiments, on insertion into the first and second sockets, the first and second memory modules may be coplanar and/or equidistant from the PCB along a third direction orthogonal to the first and second directions.

### FIELD

Embodiments of the present invention relate generally to the technical field of data processing, and more particularly, to multi-socket connectors for coupling memory modules to printed circuit boards.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure. Unless otherwise indicated herein, the approaches described in this section are not prior art to the claims in the present disclosure and are not admitted to be prior art by inclusion in this section.

As modern computer software increasingly requires more computing resources, there is a push to include more memory in computing platforms. As smaller and/or thinner computing platforms such as mobile phones and computing tablets become more prevalent, memory modules of relatively small physical size, such as small outline dual inline memory modules (“SODIMM”), are becoming more popular.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1 and 2 schematically illustrate two views of an example prior art system in which multiple memory modules are coupled to a printed circuit board (“PCB”).

FIGS. 3 and 4 schematically illustrate two views of another example prior art system in which multiple memory modules are coupled to a PCB.

FIGS. 5 and 6 schematically illustrate two views of another example prior art system in which multiple memory modules are coupled to a PCB.

FIGS. 7 and 8 schematically illustrate two views of an example system in which multiple memory modules are coupled to a PCB, in accordance with various embodiments of the present disclosure.

FIG. 9 illustrates example eye heights and widths of an eye oscilloscope pattern that may be achieved using two different memory module connectors, in accordance with various embodiments of the present disclosure.

FIG. 10 is a perspective view of an example memory module connector, in accordance with various embodiments of the present disclosure.

FIG. 11 is a top-down view of another example memory module connector, in accordance with various embodiments of the present disclosure.

FIG. 12 depicts an example method, in accordance with various embodiments of the present disclosure.

### DETAILED DESCRIPTION

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the terms “module” and/or “logic” may refer to, be part of, or include an Application Specific Integrated Circuit (“ASIC”), an electronic circuit, a processor (shared, dedicated, or group) and/or memory (shared, dedicated, or group) that execute one or more software or firmware programs, a combinational logic circuit, and/or other suitable components that provide the described functionality.

Multiple memory modules may be coupled to a printed circuit board (“PCB”) such as a motherboard of a computing platform in a variety of ways. In a two-memory-module-per-channel implementation, a memory module may be coupled on each side of the PCB, or both may be coupled to the same side of the PCB, e.g., in a “daisy chain” fashion. Disposing both memory modules on the same side of the PCB may enable easier access by a user than disposing the memory modules on opposite sides of the PCB.

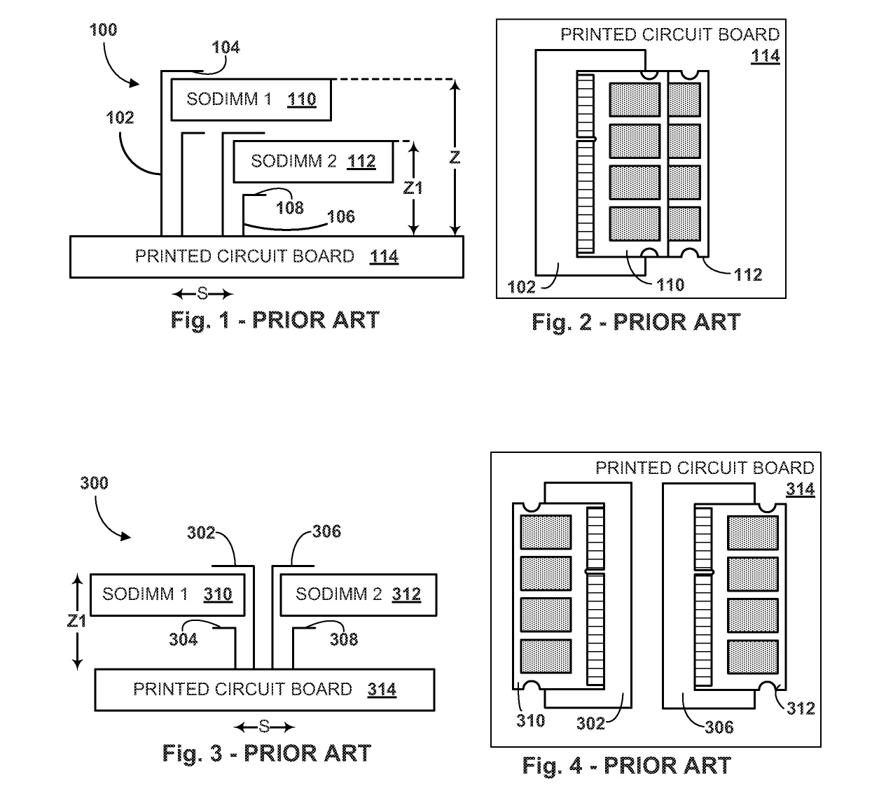

FIG. 1 schematically depicts an example prior art system 100 in which a first connector 102 having a first socket 104 and a separate, second connector 106 having a second socket 108 may be used to connect a first memory module 110 and a second memory module 112, respectively, to a PCB 114. FIG. 2 depicts a top-down view of prior art system 100. First connector 102 may be laterally offset from second connector 106 by a distance S across PCB 114. This portion of PCB 114 may be highly electrically sensitive, and thus, the distance S may impact the electrical behavior of one or more channels. For example, as the distance S increases, the electrical signal integrity margin to failure may decrease, which may negatively affect channel performance. Mechanical limitations of two separate connectors in accordance with the prior art arrangement as shown in FIGS. 1 and 2 may limit how much the distance S may be reduced.

In addition to the offset between first connector 102 and second connector 106, first connector 102 may be sized so that when first memory module 110 is inserted into first socket 104, first memory module is offset from PCB 114 by a distance Z. Second connector 106 may be sized so that when second memory module 112 is inserted into second socket 108, second memory module 112 is offset from PCB 114 by a distance Z1. As the distance Z increases, system 100 may become less suitable for use in thin computing platforms such as smart phones and tablet computers. Likewise, decreasing the distance Z may enable computing platforms that incorporate system 100 to be made thinner. However, mechanical limitations of memory modules and the configuration of first connector 102 and second connector 106 may limit how much the distance Z can be reduced. For example, the distance Z between first memory module 110 and PCB 114 may be approximately 9.2 mm. The distance Z1 between second memory module 112 and PCB 114 may be approximately 5.2 mm.

FIG. 3 schematically depicts another example prior art system 300 in which a first connector 302 having a first socket 304 and a separate, second connector 306 having a second socket 308 may be used to couple a first memory module 310 and a second memory module 312, respectively, to a PCB 314. FIG. 4 depicts a top-down view of prior art system 300. In this example, first connector 302 and second connector 306 may be oriented so that first memory module 310 is inserted into first socket 304 from one direction and second memory module 312 is inserted into second socket 308 from an opposite direction. This enables first connector 302 and second connector 306 to be sized so that when first memory module 310 and second memory module 312 are inserted into first socket 304 and second socket 308, respectively, first memory module 310 and second memory module 312 are equidistant from PCB 314, e.g., by the distance Z1. In various embodiments, Z1may be less than Z in FIG. 1, e.g., 5.2 mm rather than 9.2 mm. Decreasing this distance between the memory modules and PCB 314 may enable computing platforms such as mobile phones and tablet computers to be made thinner. However, first connector 302 may still be laterally offset from second connector 306 by a distance S, similar to the prior art example of FIG. 1, which may present the same electrical issues.

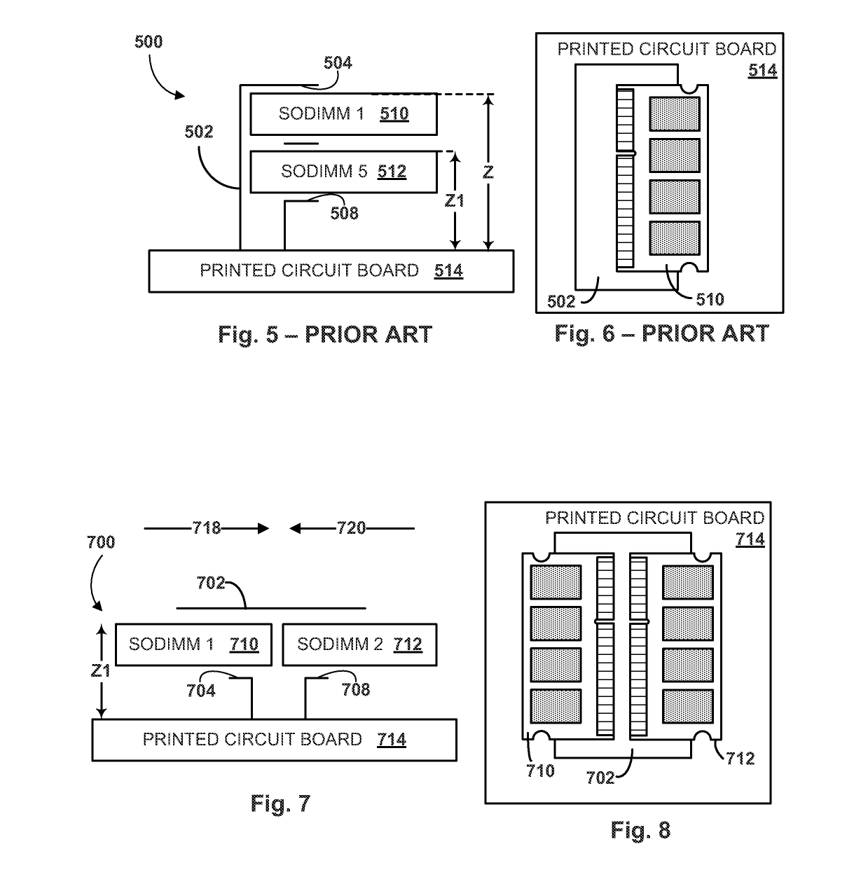

FIG. 5 schematically depicts another example prior art system 500 for coupling memory modules with a PCB. Unlike previous examples, prior art system 500 includes a single connector 502 having a first socket 504 and a separate, second socket 508. Single connector 502 may be used to couple a first memory module 510 and a second memory module 512, respectively, to a PCB 514. FIG. 6 depicts a top-down view of prior art system 500. Because there is only the single connector 502, the distance S is reduced or eliminated. However, first memory module 510 may still be offset from PCB 514 by a distance Z, which as noted above may limit how thin computing platforms may be manufactured.

FIG. 7 depicts an example system 700 for coupling memory modules with a PCB that reduces both the distances S and Z, in accordance with various embodiments of the present disclosure. This may facilitate both the manufacture of thinner computing devices and at least partially ameliorate the above-mentioned electrical issues caused by the distance S between multiple separate connectors. System 700 may include a single multi-socket connector 702 having a first socket 704 and a second socket 708. FIG. 8 depicts a top-down view of system 700.

First socket 704 and second socket 708 may be oriented so that first memory module 710 may be inserted into first socket 704 from a first direction 718 and second memory module 712 may be inserted into second socket 708 from a second, opposite direction 720. This way, when first memory module 710 and second memory module 712 are inserted into first socket 704 and second socket 708, respectively, and the assembly is viewed from the side, it may resemble a “T.” Accordingly, it may be referred to as a “T-connector.” In various embodiments, once inserted into first socket 704 and second socket 708, respectively, first memory module 710 and second memory module 712 may be equidistant from PCB 714, e.g., by a distance Z1 in a direction that is orthogonal to the first and second directions. In various embodiments, the distance Z1 may be less than 5.8 mm, e.g., approximately 5.2 mm. In various embodiments, on insertion, first memory module 710 and second memory module 712 may be coplanar with each other. In other embodiments, the memory modules on insertion may not be precisely coplanar and/or may not be precisely equidistant from PCB 714, though in general the memory module with the higher distance Z may still be closer to PCB 714 than with the aforementioned prior art connectors. Due to the single multi-socket connector 702, the distance S may be reduced or eliminated altogether. For example, in various embodiments, on insertion, first memory module 710 and second memory module 712 may be separated from each other on a plane by less than 100 mils.

In addition to decreasing S and Z, the manner in which multi-socket connector 702 receives memory modules may permit more air flow on both sides of the memory modules than other configurations, such as the prior art stacked configurations shown in FIGS. 1-2 and 5-6. In various embodiments, air flow may be improved further by mounting multi-socket connector 702 on PCB 714 so that one or more memory modules overhang an edge of PCB 714, or so that one or more memory modules overhang a cut in PCB 714. Additionally, the non-stacked, T-shaped manner in which multi-socket connector 702 receives memory modules may reduce parasitic effects on memory modules caused by, e.g., copper traces and other components of PCB 714. It may also reduce inductance and resistance between power rails of the memory modules, as compared to two-memory-module-per-channel implementations. There also may be less of a voltage drop across multi-socket connector 702, as well as well general noise, than might be present across connectors used in other two-memory-module-per-channel implementations.

In various embodiments, multi-socket connector 702 may facilitate improved power decoupling over other types of connectors when power supplied to memory modules changes abruptly. For instance, it may be possible to dispose a decoupling element such as a capacitor closer to memory modules inserted into sockets of multi-socket connector 702 than to memory modules inserted into other types of connectors. In various embodiments, the decoupling element may be embedded inside of multi-socket connector 702. This may simplify layout of components on PCB 714, and may provide a power delivery path for high frequency switching noise.

In various embodiments, multi-socket connector 702 may be configured to respectively relay, to first memory module 710 and second memory module 712, from PCB 714, first and second separate, dedicated control signals and/or dedicated clock signals. However, in various embodiments, other signals, such as data signals and/or command signals, may be shared. For example, in various embodiments, multi-socket connector 702 may be configured to provide first memory module 710 and second memory module 712 with a shared data pathway to and from PCB 714 and/or a shared command signal pathway from PCB 714.

Connectors described herein may be configured to receive various types of memory modules. For example, in the examples shown in the drawings, the connectors may be configured to removably receive small outline dual inline memory modules (“SODIMMs”). However, this is not meant to be limiting, and other embodiments of connectors described herein may removably receive any type of dynamic or static memory modules, such as other types of DIMMs, double data rate synchronous dynamic random access memory (“DDR SDRAM”) of any vintage (e.g., DDR3, DDR4, etc.), Zero-Capacitor RAM (“Z-RAM”), twin transistor RAM (“TTRAM”), and any past, present or future memory technologies. Additionally, in various embodiments, memory modules may include various other types of memory, such as non-volatile random access memory (“NVRAM,” e.g., flash memory), ferroelectric random-access memory (“FeTRAM”), nanowire-based NVM, phase change memory (“PCM”), and so forth.

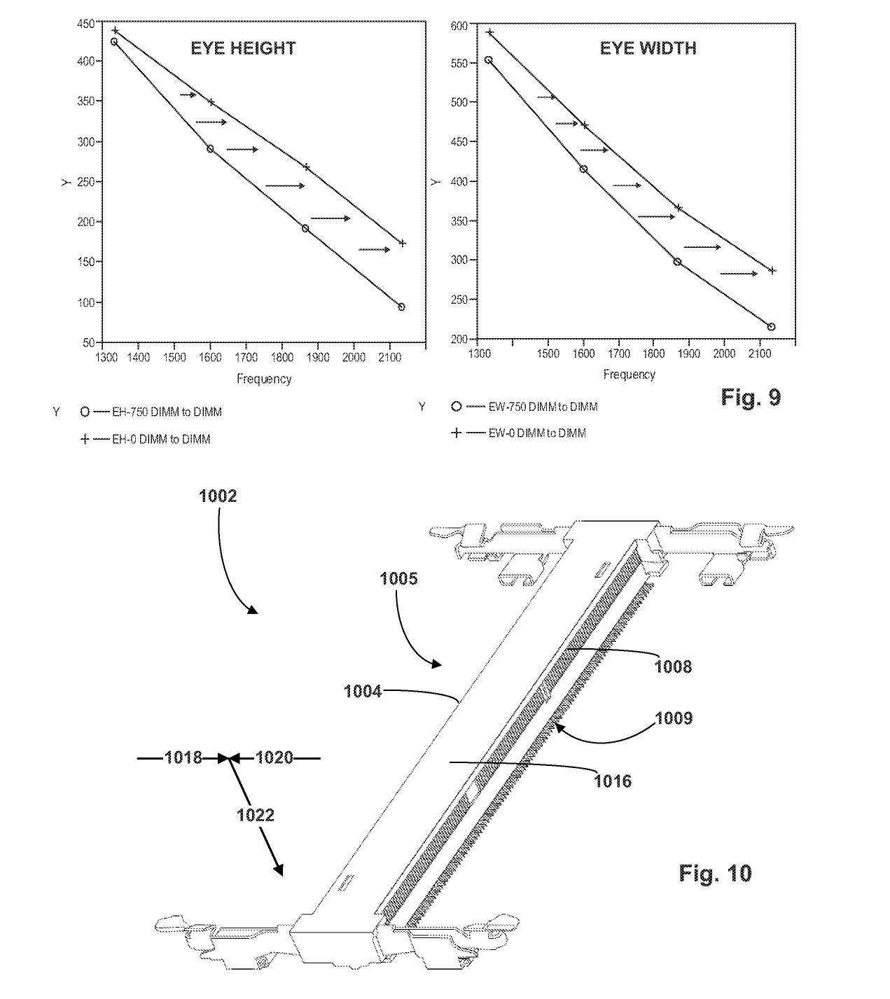

In FIG. 9, example eye heights and widths from an eye oscilloscope pattern generated from channel analysis are shown for two different memory module connectors, one from the prior art and another in accordance with various embodiments of the present disclosure. In the charts, the X-axis represents frequency (mega transfers per second, or “MT/s”) and the Y-axis represents the eye dimension (height and width, respectively). Results from a first system (e.g., 100, 300) having a distance S of 750 mils between a first connector (e.g., 102, 302) and a second connector (e.g., 106, 306) is represented by the line with the intermittent circles. Results from a second system (e.g., 700) having a distance S of 0 mils (because there is only one connector, e.g., 702) is represented by the line with intermittent plus signs. As seen in these charts, both the eye heights and widths increase at all frequencies where the distance S is reduced from 750 mils to 0. The general trend shown by the arrows may correspond to higher performance when S is reduced.

FIG. 10 depicts an example multi-socket connector 1002, similar to multi-socket connector 702 in FIGS. 8 and 9, which likewise may be referred to as a T-connector, in accordance with various embodiments of the present disclosure. Multi-socket connector 1002 may include a longitudinal body 1016 configured to mount multi-socket connector 1002 to a PCB (not shown in FIG. 10). A first socket 1004 and a second socket 1008 may be respectively disposed at a first side 1005 and a second side 1009 of longitudinal body 1016 of multi-socket connector 1002, to removably receive a first memory module (not shown in FIG. 10) from a first direction 1018 and a second memory module (not shown in FIG. 10) from a second direction 1020 opposite to the first direction. In various embodiments, second side 1009 may be opposite to first side 1005. In various embodiments, on insertion into the first and second sockets, the first and second memory modules may be coplanar, and may be equidistant from an underlying PCB by a distance in a third direction 1022. In various embodiments, the first and second sockets 1004, 1008 may be disposed at a top end of longitudinal body 1016. In various embodiments, the bottom end of longitudinal body 1016 may be wider than the top end, which may increase stability of multi-socket connector 1002.

In various embodiments, providing dedicated control and clock signals to each memory module may increase the number of overall pins. For instance, in embodiments where the connector is configured to receive two SODIMMs, dedicated control and clock signals may increase the total number of pins by 21, e.g., from 204 pins to 225 pins.

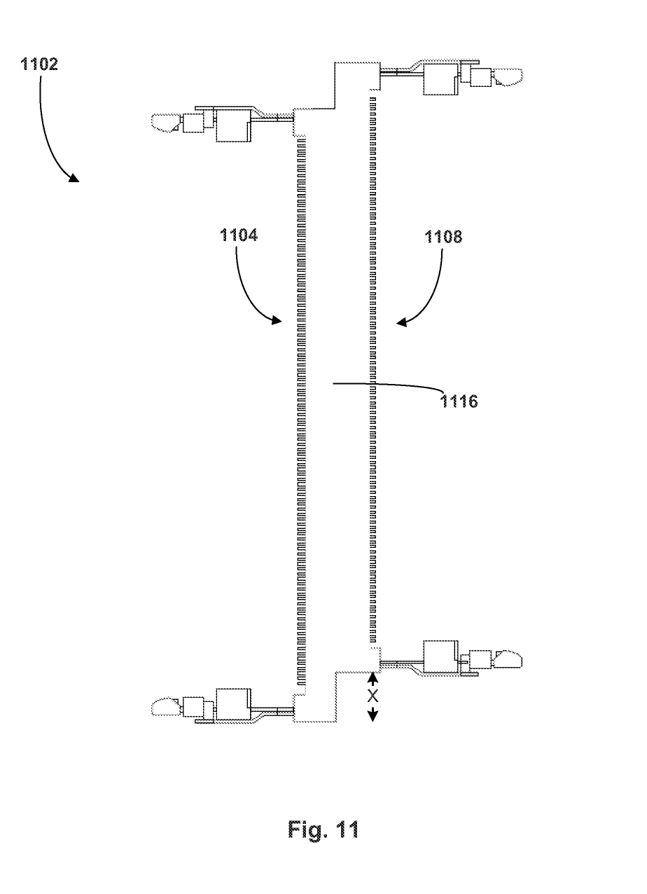

FIG. 11 depicts another example multi-socket connector 1102 similar to multi-socket connector 702 in FIGS. 8 and 9 and 1002 in FIG. 10, which likewise may be referred to as a T-connector, in accordance with various embodiments of the present disclosure. However, multi-socket connector 1102 in FIG. 11 has two sockets, 1104 and 1108, respectively, on opposite sides of a longitudinal body 1116, that are offset from each other by a distance X in a direction that may be orthogonal to both directions from which memory modules may be inserted, and/or to a direction between the memory modules and an underlying PCB (not shown). In various embodiments, providing such an offset may enable contact pins to be placed in an alternating fashion, e.g., to ease manufacturing.

Multi-socket connectors (e.g., 702, 1002, 1102) may be used in various types of computing platforms, including but not limited to a laptop, a netbook, a notebook, an ultrabook, a smart phone, a computing tablet, a personal digital assistant (“PDA”), an ultra mobile PC, a mobile phone, a desktop computer, a server, a printer, a scanner, a monitor, a set-top box, an entertainment control unit (e.g., a gaming console), a digital camera, a portable music player, a digital video recorder, an so forth. In various implementations, multi-socket connectors may be used in any other electronic device that processes data.

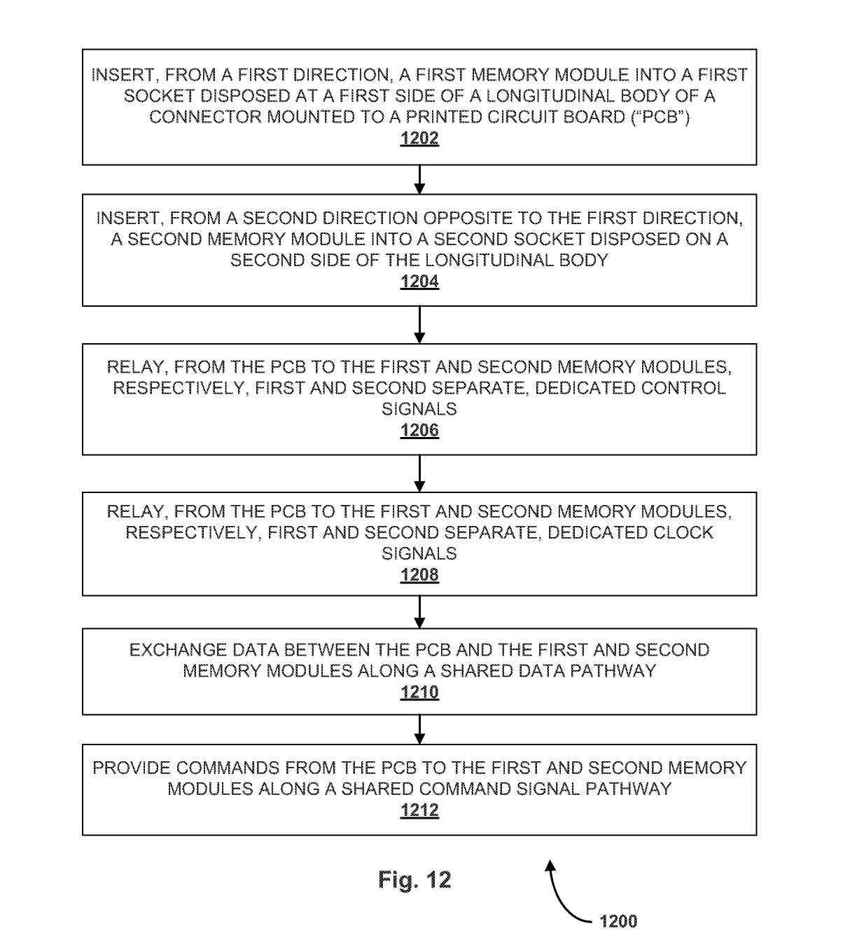

FIG. 12 depicts an example method 1200 that may be implemented in accordance with various embodiments of the present disclosure. Although operations are shown in a particular order, this should not be construed as limiting, and one or more operations may be reordered and/or omitted. At block 1202, a first memory module (e.g., 710) may be inserted, from a first direction (e.g., 718, 1018) into a first socket (e.g., 704, 1004, 1104) disposed at a first side of a longitudinal body (e.g., 1016, 1116) of a connector (e.g., 702, 1002, 1102) mounted to a PCB (e.g., 714). At block 1204, a second memory module (e.g., 712) may be inserted, from a second direction (e.g., 720, 1020) into a second socket (e.g., 708, 1008, 1108) disposed at a second side of a longitudinal body (e.g., 1016, 1116) of a connector (e.g., 702, 1002, 1102) mounted to a PCB (e.g., 714).

At block 1206, first and second separate, dedicated control signals may be relayed from the PCB (e.g., 714) to the first and second memory modules, respectively. At block 1208, first and second separate, dedicated clock signals may be relayed from the PCB (e.g., 714) to the first and second memory modules, respectively. At block 1210, data may be exchanged between the PCB (e.g., 714) and the first and second memory modules along a shared data pathway. At block 1212, commands may be provided from the PCB (e.g., 714) to the memory modules along a shared command signal pathway.

Embodiments of apparatus, methods, systems, devices, and connectors are described herein for a connector having a longitudinal body configured to mount the connector to a PCB. In various embodiments, a first and a second socket may be respectively disposed at a first side and a second side of the longitudinal body. In various embodiments, the first and second sockets may removably receive a first memory module from a first direction and a second memory module from a second direction opposite to the first direction. In various embodiments, the second side may be opposite to the first side. In various embodiments, on insertion into the first and second sockets, the first and second memory modules may be coplanar and/or equidistant from the PCB along a third direction orthogonal to the first and second directions.

In various embodiments, on insertion into the first and second sockets, each of the first and second memory modules may be less than 5.8 mm from the PCB. For instance, in various embodiments, after insertion into the first and second sockets, each of the first and second memory modules may be approximately 5.2 mm from the PCB.

In various embodiments, the body may be further configured to respectively relay to the first and second memory modules, from the PCB, first and second separate, dedicated control signals. In various embodiments, the body may be further configured to respectively relay to the first and second memory modules, from the PCB, first and second separate, dedicated clock signals.

In various embodiments, the body may be further configured to provide the first and second memory modules with a shared data pathway to and from the PCB. In various embodiments, the body may be further configured to provide the first and second memory modules with a shared command signal pathway from the PCB.

In various embodiments, the first and second sockets may be configured to removably receive first and second memory modules that are SODIMMs. In various embodiments, the body further may include a top end and a bottom end, the first and second sockets being disposed at the top end, and the top end may be wider than the bottom end. In various embodiments, the first and second sockets may be coplanar and separated from each other on a plane by less than 100 mils. In various embodiments, the first and second sockets may be offset from each other in a direction parallel to the longitudinal body.

Although certain embodiments have been illustrated and described herein for purposes of description, this application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

1. A connector comprising:
a longitudinal body configured to mount the connector to a printed circuit board (“PCB”); and
a first and a second socket respectively disposed at a first side and a second side of the longitudinal body, to removably receive a first memory module from a first direction and a second memory module from a second direction opposite to the first direction, the second side being opposite to the first side,
wherein on insertion into the first and second sockets, the first and second memory modules are coplanar.

2. The connector of claim 1, wherein on insertion into the first and second sockets, the first and second memory modules are equidistant from the PCB along a third direction orthogonal to the first and second directions.

3. The connector of claim 1, wherein on insertion into the first and second sockets, each of the first and second memory modules is less than 5.8 mm from the PCB.

4. The connector of claim 1, wherein after insertion into the first and second sockets, each of the first and second memory modules is approximately 5.2 mm from the PCB.

5. The connector of claim 1, wherein the body is further configured to respectively relay to the first and second memory modules, from the PCB, first and second separate, dedicated control signals.

6. The connector of claim 1, wherein the body is further configured to respectively relay to the first and second memory modules, from the PCB, first and second separate, dedicated clock signals.

7. The connector of claim 1, wherein the body is further configured to provide the first and second memory modules with a shared data pathway to and from the PCB.

8. The connector of claim 1, wherein the body is further configured to provide the first and second memory modules with a shared command signal pathway from the PCB.

9. The connector of claim 1, wherein the first and second sockets are configured to removably receive first and second memory modules that are small outline dual inline memory modules (“SODIMMs”).

10. The connector of claim 1, wherein the body further comprises a top end and a bottom end, the first and second sockets being disposed at the top end, and the top end being wider than the bottom end.

11. The connector of claim 1, wherein the first and second sockets are coplanar and separated from each other on a plane by less than 100 mils.

12. The connector of claim 1, wherein the first and second sockets are offset from each other in a direction parallel to the longitudinal body.

13. A system, comprising:
a printed circuit board (“PCB”);
a single connector mounted to the PCB for coupling first and second memory modules to the PCB, the connector comprising a first socket configured to receive a first memory module from a first direction, and a second socket configured to receive a second memory module from a second direction opposite to the first direction; and
first and second memory modules removably inserted into the first and second sockets of the single connector from the first and second directions, respectively, wherein after insertion into the first and second sockets, the first and second memory modules are coplanar and equidistant from the PCB along a third direction orthogonal to the first and second directions.

14. The system of claim 13, wherein on insertion into the first and second sockets, each of the first and second memory modules is less than 5.8 mm from the PCB.

15. The system of claim 13, wherein after insertion into the first and second sockets, each of the first and second memory modules is approximately 5.2 mm from the PCB.

16. The system of claim 13, wherein the connector is further configured to respectively relay to the first and second memory modules, from the PCB, first and second separate, dedicated control signals or first and second separate, dedicated clock signals.

17. The system of claim 13, wherein the connector is further configured to provide the first and second memory modules with a shared data pathway to and from the PCB or a shared command signal pathway from the PCB.

18. The system of claim 13, wherein the first and second sockets are configured to removably receive first and second memory modules that are small outline dual inline memory modules (“SODIMMs”).

19. The system of claim 13, wherein the connector further comprises a top end and a bottom end, the first and second sockets being disposed at the top end, and the top end being wider than the bottom end.

20. The system of claim 13, wherein the first and second sockets are coplanar and separated from each other on a plane by less than 100 mils.

21. The system of claim 13, wherein the first and second sockets are offset from each other in a fourth direction orthogonal to the first, second and third directions.

22. The system of claim 13, further comprising a touch screen display.

23. A method comprising:
inserting, from a first direction, a first memory module into a first socket disposed at a first side of a longitudinal body of a connector mounted to a printed circuit board (“PCB”); and
inserting, from a second direction opposite to the first direction, a second memory module into a second socket disposed on a second side of the longitudinal body;
wherein on insertion into the first and second sockets, the first and second memory modules are equidistant from the PCB along a third direction orthogonal to the first and second directions.

24. The method of claim 23, wherein on insertion into the first and second sockets, the first and second memory modules are coplanar.

25. The method of claim 23, further comprising relaying, from the PCB to the first and second memory modules, respectively, first and second separate, dedicated control signals.

26. The method of claim 23, further comprising relaying, from the PCB to the first and second memory modules, respectively, first and second separate, dedicated clock signals.

27. The method of claim 23, further comprising exchanging data between the PCB and the first and second memory modules along a shared data pathway.

28. The method of claim 23, further comprising providing commands from the PCB to the first and second memory modules along a shared command signal pathway.
